(19) United States
(12) Patent Application Publication
(10) Pub. No.: US 2015/0371991 A1
(43) Pub. Date: Dec. 24, 2015

(54) SEMICONDUCTOR DEVICE AND METHOD FOR MANUFACTURING SAME

(71) Applicant: Hidekazu NOBUTO, (US)

(72) Inventor: Hidekazu Nobuto, Tokyo (JP)

(21) Appl. No.: 14/765,792

(22) PCT Filed: Feb. 3, 2014
(86) PCT No.: PCT/JP2014/052437

§ 371 Date: Aug. 4, 2015

(30) Foreign Application Priority Data
Feb. 7, 2013 (JP) 2013-021979

(51) Int. Cl. H01L 27/108; H01L 29/423; H01L 29/49; H01L 21/28

(52) U.S. Cl. CPC H01L 27/10823; H01L 21/28088; H01L 29/4236; H01L 27/10876; H01L 29/4966

(57) ABSTRACT

One semiconductor device includes an active region on a semiconductor substrate, a trench having a lower section and an upper section within the active region, a gate insulating film that covers the inner wall surface of the trench, a first barrier metal that covers the lower section of the trench interposed by the gate insulating film, a second barrier metal that covers the first barrier metal, and a metal electrode that covers the second barrier metal and fills up the lower section of the trench. The second barrier metal is thinner than the first barrier metal.

### TECHNICAL FIELD

The present invention relates to a semiconductor device and to a method for manufacturing same, and in particular the present invention relates to effective technology for application to a semiconductor device comprising a DRAM (dynamic random access memory) employing an embedded word line structure.

### BACKGROUND

A DRAM, which is a type of semiconductor memory device, is installed in a large number of varying electronic devices used by people in daily life. Furthermore, there is also a strong demand for higher performance from installed DRAMs, in terms of reduced power, higher speed and higher capacity, which has come about with the recent need for lower power consumption and higher performance in devices.

One of the most effective means for achieving high performance in a DRAM is to miniaturize a memory cell. The length of word lines and bit lines connected to the memory cell decreases as a result of miniaturizing the memory cell. The parasitic capacitance of the word lines and bit lines is therefore reduced, which enables low-voltage operation, so a reduction in power consumption can be achieved. Furthermore, the memory cell is small in size, so increased capacity can be achieved and a high-performance device can be produced. Miniaturization of the memory cell thus makes a large contribution to higher performance in a DRAM.

As memory cells comprising a cell transistor provided in this kind of semiconductor device become miniaturized, this leads to problems such as a deterioration in transistor characteristics caused by the short channel effect, and an increase in contact resistance caused by a reduction in the diameter of contact holes.

In order to solve these problems and to promote further miniaturization, the use of an embedded gate transistor, in which a gate electrode constituting a word line is embedded in the surface of a semiconductor substrate, has been proposed for a cell transistor forming part of a memory cell.

For example, JP 2008-028055 A (Patent Document 1) describes a method for manufacturing a semiconductor device, in which an insulating film (sacrificial oxide film) is formed by CVD (chemical vapor deposition) on a main surface of a semiconductor substrate (silicon substrate), a silicon nitride film is deposited thereon, the insulating film (sacrificial oxide film) and the semiconductor substrate (silicon substrate) are etched using the silicon nitride film as a mask in order to form a trench, and the semiconductor substrate (silicon substrate) is subjected to thermal oxidation whereby a gate insulating film for a memory cell transistor is formed on the inner walls of the trench, and a conductive film (polycrystalline silicon film doped with n-type impurity) for the gate electrode is formed (deposited) by means of CVD on the insulating film (sacrificial oxide film) including the inside of the trench. Moreover, Patent Document 1 indicates in regard to the conductive film that an amorphous silicon film may be deposited instead of the polycrystalline silicon film and p-type impurity (boron) may be used for the doping instead of n-type impurity.

Furthermore, JP 2012-099793 A (Patent Document 2) describes a method for manufacturing a semiconductor device, in which a mask insulating film having a pattern with openings is formed on the upper surface of a semiconductor substrate, the semiconductor substrate is etched using the mask insulating film as a mask to form a gate trench, a gate insulating film comprising a silicon dioxide film is formed by means of thermal oxidation on the inner surface of the gate trench, titanium nitride (TiN) is formed by means of CVD, tungsten (W) is formed by means of CVD, a laminated film comprising TiN and W is etched back by means of dry etching in order to form an embedded gate electrode (word line) comprising TiN and W which is embedded in the gate trench, and a cap insulating film comprising a silicon nitride film is formed by means of CVD in such a way as to fill the new gate trench formed above the embedded gate electrode.

### PATENT DOCUMENTS

Patent Document 1: JP 2008-028055 A (paragraphs [0048]-[0052] and FIG. 3 to FIG. 6)
Patent Document 2: JP 2012-099793 A (paragraphs [0046]-0049) and FIG. 10 to FIG. 13)

### SUMMARY OF THE INVENTION

### Problem to be Solved by the Invention

Miniaturization of the 65 nm node, 25 nm node and 20 nm node memory cells is progressing. Memory cells of the 65 nm and subsequent node employ an embedded word line structure in which tungsten (W) is embedded in a trench structure formed by etching a semiconductor substrate (silicon substrate) such as that described in abovementioned Patent Document 2. The trench width is 65 nm for the 65 nm node, 26 nm for the 25 nm node, and 12 nm for the 20 nm node.

The trench width in a 20 nm node memory cell is reduced as far as 12 nm, as mentioned above, so it is necessary to make the titanium nitride (TiN) film and the tungsten (W) core-formation film as thin as possible. Moreover, the titanium nitride (TiN) is also referred to as a barrier metal, and the tungsten (W) is also referred to as a metal electrode.

However, there are problems with a conventional film formation method (production method) employing CVD in that it is not possible to form a thin barrier metal film, to maintain adhesion with the metal electrode and to control/manage the thickness of the thin film.

### Means for Solving the Problem

A semiconductor device of the present invention comprises: an active region on a semiconductor substrate; a trench inside the active region having a lower part and an upper part; a gate insulating film covering the inner wall surface of the trench; a first barrier metal covering the trench lower part with the gate insulating film interposed; a second barrier metal covering the first barrier metal; a metal electrode which covers the second barrier metal and fills the trench lower part; and a cap insulating film filling the trench upper part, the film thickness of the second barrier metal being less than the film thickness of the first barrier metal.

Furthermore, according to a method for manufacturing a semiconductor device of the present invention, a trench is formed in a semiconductor substrate, a gate insulating film is formed inside the trench, a first barrier metal is formed on the gate insulating film under a first film formation condition, a second barrier metal is formed on the first barrier metal under a second film formation condition different than the first film formation condition, a metallic material is formed on the second barrier metal in such a way as to fill the trench, the first barrier metal, second barrier metal and metal at the upper part of the trench are removed, and the trench upper part is filled with a cap insulating film.

### Advantage of the Invention

According to the present invention, the barrier metals are formed as thin films, it is possible to maintain adhesion with the metal electrode, and it is possible to control/manage the thickness of the thin film.

### BRIEF DESCRIPTION OF THE FIGURES

FIG. 1 is a plan view showing a semiconductor device (DRAM memory cell) according to a first exemplary embodiment of the present invention;

FIG. 2 is a view in the cross section A-A′ of the semiconductor device shown in FIG. 1;

FIG. 3 is a structural diagram in cross section showing a first production step in a process for manufacturing the semiconductor device shown in FIG. 1;

FIG. 4 is a structural diagram in cross section showing a second production step in the process for manufacturing the semiconductor device shown in FIG. 1;

FIG. 5 is a structural diagram in cross section showing a third production step in the process for manufacturing the semiconductor device shown in FIG. 1;

FIG. 6 is a structural diagram in cross section showing a fourth production step in the process for manufacturing the semiconductor device shown in FIG. 1;

FIG. 7 is a structural diagram in cross section showing a fifth production step in the process for manufacturing the semiconductor device shown in FIG. 1;

FIG. 8 is a structural diagram in cross section showing a sixth production step in the process for manufacturing the semiconductor device shown in FIG. 1;

FIG. 9 is a structural diagram in cross section showing a seventh production step in the process for manufacturing the semiconductor device shown in FIG. 1; and

FIG. 10 is a structural diagram in cross section showing a eighth production step in the process for manufacturing the semiconductor device shown in FIG. 1.

### MODE OF EMBODIMENT OF THE INVENTION

### Related Technology

Related technology will be described before a description of the present invention is given, in order to facilitate an understanding of the present invention.

A method for forming a related embedded word line structure will be described below.

An element isolation region filled by an insulating film comprising a silicon dioxide film is first of all formed on a semiconductor substrate (silicon substrate) by means of known STI (shallow trench isolation). An active region surrounded by the element isolation region and comprising the semiconductor substrate (silicon substrate) is formed as a result.

A first interlayer insulating film comprising silicon nitride (SiN) or silicon dioxide (SiO₂) is then formed over the whole surface of the semiconductor substrate (silicon substrate), and patterning is carried out, after which a trench (gate trench) is formed by dry etching.

The surface of the trench is then oxidized by means of thermal oxidation (ISSG: in-situ steam generation), whereby a gate insulating film comprising a silicon dioxide film is formed.

A barrier metal comprising titanium nitride (TiN) is then formed on the gate insulating film as an electrode by means of thermal CVD (chemical vapor deposition) employing titanium tetrachloride (TiCl₄) gas and ammonia (NH₃).

The tungsten (W) core formation is conventionally carried out while alternately purging with a tungsten hexafluoride (WF₆) flow and a monosilane (SiH₄) flow, or a tungsten hexafluoride (WF₆) flow and a diborane (B₂H₆) flow, or a tungsten hexafluoride (WF₆) flow and a hydrogen (H₂) flow.

At this stage, the trench is in a state in which it is completely filled by a laminated film comprising titanium nitride (TiN) and tungsten (W).

The laminated film comprising titanium nitride (TiN) and tungsten (W) is then etched back by means of dry etching and an embedded gate electrode comprising titanium nitride (TiN) and tungsten (W) embedded inside the trench is formed. This embedded gate electrode constitutes a word line. As a result of the embedded gate electrode being formed inside the trench, a new trench is formed above the embedded gate electrode.

A cap insulating film comprising silicon nitride (SiN) is then formed over the whole surface by means of CVD in such a way as to fill the new trench, and the surface silicon nitride (SiN) film is removed.

The problems of the related technology will be described next.

The trench width in a 20 nm node memory cell is reduced as far as 12 nm, as mentioned above, so it is necessary to make the titanium nitride (TiN) film and the tungsten (W) core-formation film as thin as possible.

However, when use is made of a barrier metal comprising inorganic titanium nitride (TiN) which is formed as a film by conventional CVD, the thickness of the barrier metal film comprising titanium nitride (TiN) can be reduced only as far as 3 nm, a level at which there is no problem of adhesion with the metal electrode comprising tungsten (W). It is therefore not possible to reduce the word line resistance.

Furthermore, by deliberately varying the gas condition of the titanium nitride (TiN) from a reaction rate-controlled region to a supply rate-controlled region so that the coverage is changed from 100% to around 50%, the thickness of the titanium nitride (TiN) film inside the trench can be reduced and the thickness of the titanium nitride (TiN) film in the trench upper part can be increased.

A simple explanation will be given below of the terms “reaction rate-controlled” and “supply rate-controlled”.

The rate of epitaxial growth afforded by CVD depends on the type of starting material gas, temperature and pressure, among other things. The temperature region in which epitaxial growth is possible (the growth temperature region) is divided into two regions in qualitative terms, namely a reaction rate-controlled region and a supply rate-controlled region. Supply rate-controlled is also referred to as diffusion rate-controlled. The reaction rate-controlled region is on the low-temperature side within the growth temperature region and the growth rate increases the higher the temperature. On the other hand, the supply rate-controlled region is on the high-temperature side of the same region and has little temperature dependency. Epitaxial growth normally takes place in this supply rate-controlled region.

As a result of the abovementioned variation, it is possible to achieve a balance between improving adhesion with the metal electrode comprising tungsten (W) and reducing the thickness of the barrier metal film comprising a titanium nitride (TiN) film inside the trench. However, under a supply rate-controlled condition, the barrier metal comprising titanium nitride (TiN) varies when the surface area of the pattern varies, so there is a problem in that it is not possible to control/manage the thickness of the barrier metal film comprising a titanium nitride (TiN) film.

The aim of the present invention therefore lies in providing a semiconductor device and a method for manufacturing same, which make it possible to reduce the thickness of a barrier metal film, to maintain adhesion with a metal electrode, and to control/manage the thickness of the thin film.

### Mode of Embodiment

The essentials of a mode of embodiment of the present invention will be described next.

Titanium nitride (TiN) forms a discontinuous film when a film thereof is formed to a level of 3 nm or less, so there is poor adhesion with the tungsten (W) on the trench surface.

The film thickness can be controlled by a reaction rate-controlled condition, but it is not possible to reduce the thickness of the titanium nitride (TiN) film inside the trench to 3 nm or less.

Furthermore, as mentioned above, when the gas condition of the titanium nitride (TiN) is varied from the reaction rate-controlled region to the supply rate-controlled region so that the coverage is changed from 100% to 50%, adhesion with the tungsten (W) is improved and it is also possible to reduce the thickness of the titanium nitride (TiN) inside the trench to 3 nm or less. However, fluctuations in surface area have a considerable effect, so there is a problem in that the film thickness cannot be controlled/managed.

According to a mode of embodiment of the present invention, the thickness of the barrier metal film comprising a titanium nitride (TiN) film inside the trench is controlled/managed under a film formation condition of 100% coverage, and as far as adhesion with the metal electrode comprising tungsten (W) is concerned, the film formation takes place in situ in two stages under a condition such that a film can be formed only at the trench surface. As a result, there is no reduction in processing capacity, it is possible to reduce the thickness of the barrier metal film comprising a titanium nitride (TiN) film inside the trench to less than 2 nm, and ultimately it is possible to reduce word line resistance.

### Exemplary Embodiment 1

A first exemplary embodiment of the present invention will be described in detail below with reference to the figures.

In the following figures, the scale and number etc. of each structure differs from the actual structures in order to facilitate an understanding of the constituent elements. Furthermore, the arrangement of each constituent element will be described by setting an XYZ coordinate system. In this coordinate system, the Z-direction is a direction perpendicular to the surface of a silicon substrate constituting a semiconductor substrate, the X-direction is a direction orthogonal to the Z-direction in a plane which is level with the surface of the silicon substrate, and the Y-direction is a direction orthogonal to the X-direction in a plane which is level with the surface of the silicon substrate. Furthermore, the X′-direction is a direction which is obliquely inclined with respect to the X-direction.

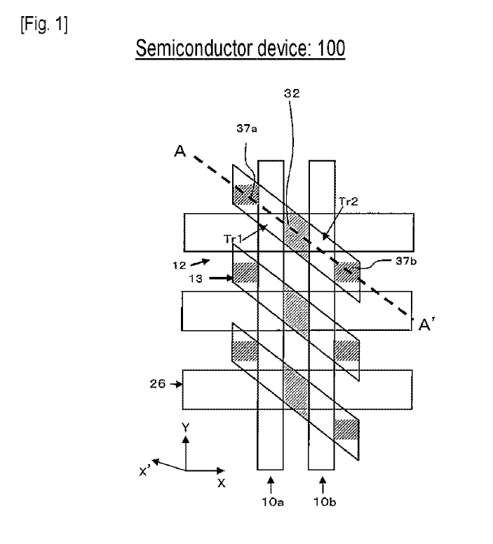

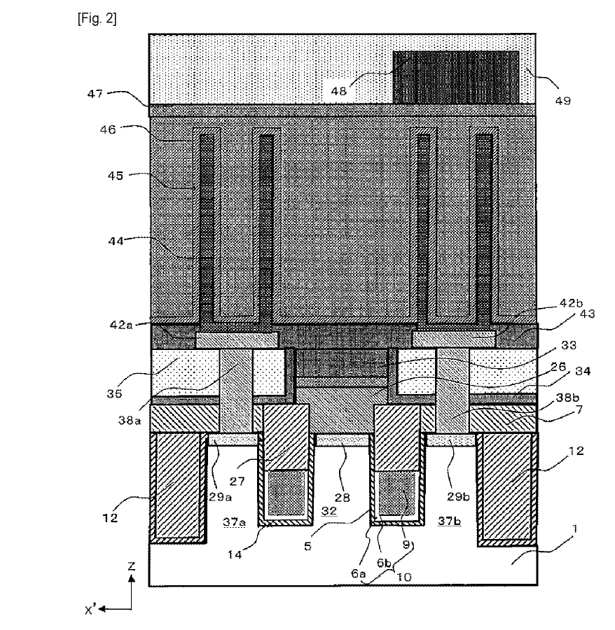

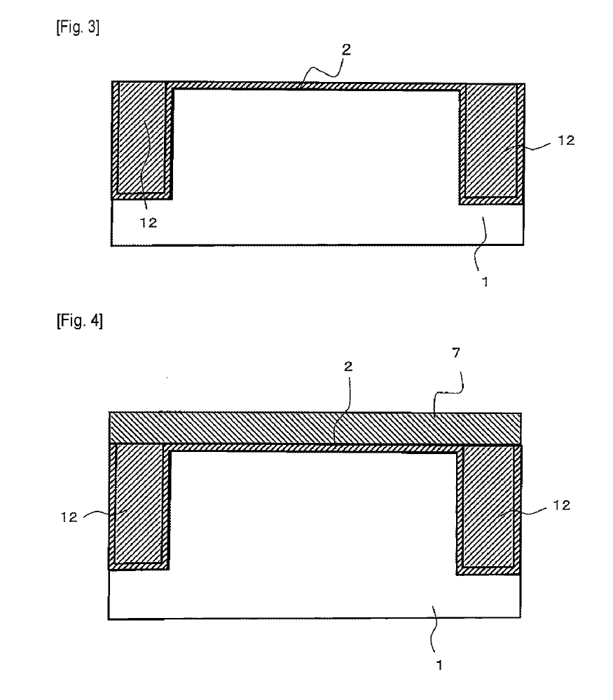

FIG. 1 to FIG. 10 show the structure of a semiconductor device 100 according to the first exemplary embodiment of the present invention, and a method for manufacturing same. The semiconductor device 100 according to the first exemplary embodiment is a DRAM (dynamic random access memory) memory cell. FIG. 1 is a plan view showing the semiconductor device 100, FIG. 2 is a view in the cross section A-A′ in FIG. 1, and FIG. 3 to FIG. 10 are views in cross section showing the series of steps in the manufacture of the semiconductor device 100.

The semiconductor device 100 according to the first exemplary embodiment will be described first of all with reference to the plan view of FIG. 1.

The semiconductor device 100 constitutes a DRAM memory cell. A plurality of element isolation regions 12 extending continuously in the X′-direction and a plurality of active regions 13 likewise extending continuously in the X′-direction are disposed at an equal pitch, at equal intervals and alternately in the Y-direction on a silicon substrate 1 (see FIG. 2) constituting a semiconductor substrate. The element isolation regions 12 are formed by an element isolation insulating film embedded in a trench. Embedded word lines 10 (10a, 10b) extending continuously in the Y-direction are disposed across the plurality of element isolation regions 12 and the plurality of active regions 13.

Here, the embedded word line 10 disposed on the left of FIG. 1 is referred to as the first word line 10a while the embedded word line 10 disposed on the right of FIG. 1 is referred to as the second word line 10b.

A first capacitance contact region 37a is disposed adjacently to the left of the first word line 10a, and a second capacitance contact region 37b is disposed adjacently to the right of the second word line 10b. A bit line contact region 32 is disposed adjacently between the first word line 10a and the second word line 10b.

The active regions 13 comprise the first capacitance contact region 37a, the first word line 10a, the bit line contact region 32, the second word line 10b and the second capacitance contact region 37b. A first cell transistor Tr1 is formed by the first capacitance contact region 37a, the first word line 10a and the bit line contact region 32. A second cell transistor Tr2 is formed by the bit line contact region 32, the second word line 10b and the second capacitance contact region 37b.

Referring next to FIG. 2, word line gate trenches 14 also serving as transistor gate electrodes are provided in the silicon substrate 1. The first word line 10a and the second word line 10b are provided in the bottom part of respective gate trenches 14, with the interposition of a gate insulating film 5 formed by a thermally-oxidized film covering the inner surface of each word line gate trench 14. A cap insulating film 27 is provided embedded in each gate trench 14 covering the respective word lines.

A semiconductor pillar positioned to the left of the first word line 10a forms the first capacitance contact region 37a, and an impurity diffusion layer 29a forming either of a source/drain is provided on the upper surface thereof. A semiconductor pillar positioned between the first word line 10a and the second word line 10b forms the bit line contact region 32, and an impurity diffusion layer 28 forming the other of the source/drain is provided on the upper surface thereof

Furthermore, a semiconductor pillar positioned to the right of the second word line 10b forms the second capacitance contact region 37b, and an impurity diffusion layer 29b forming either of a source/drain is provided on the upper surface thereof

The first transistor Tr1 (FIG. 1) is formed by the impurity diffusion layer 29a, the gate insulating film 5, the first word line 10a and the impurity diffusion layer 28. Furthermore, the second transistor Tr2 (FIG. 1) is formed by the impurity diffusion layer 28, the gate insulating film 5, the second word line 10b and the impurity diffusion layer 29b. The cap insulating film 27 is provided in such a way as to cover the upper surface of the respective word lines.

A first interlayer insulating film 7 comprising a silicon dioxide film which is employed as a mask when the gate trenches 14 are formed is provided on the upper surfaces of the element isolation regions 12 and the upper surface of the silicon substrate 1 on which the impurity diffusion layers 29a, 29b are formed.

A bit line (BL) 26 connected to the impurity diffusion layer 28 in the bit line contact region 32 is provided on the cap insulating film 27. A cover insulating film 33 is provided on the upper surface of the BL 26. A liner insulating film 34 is provided over the whole surface in such a way as to cover the side walls of the BL 26. A SOD (spin-on dielectric) film 35 filling a recessed space formed between adjacent BL is provided on the liner insulating film 34.

Two capacitance contact holes are provided running through the SOD film 35, liner film 34 and first interlayer insulating film 7. The first and second capacitance contact plugs 38a, 38b are connected to the first and second capacitance contact regions 37a, 37b by means of these capacitance contact holes. First and second capacitance contact pads 42a, 42b are connected to the upper part of the first and second capacitance contact plugs 38a, 38b, respectively. A stopper nitride film 43 is provided in such a way as to cover the capacitance contact pads 42. A capacitor lower electrode 44 is provided on the capacitance contact pad 42. A capacitance insulating film 45 covering the inner surface of the capacitor lower electrode 44 is provided, a capacitor upper polysilicon electrode 46 is provided on the capacitance insulating film 45, and a capacitor upper tungsten electrode 47 is provided.

Wiring 48 and a second interlayer insulating film 49 are then provided on the capacitor upper tungsten electrode 47.

The method for manufacturing the semiconductor device 100 shown in FIG. 1 and FIG. 2 will be described below with the aid of FIG. 3 to FIG. 10. FIG. 3 to FIG. 10 are views in the cross section A-A′ in FIG. 1.

First of all, as shown in FIG. 3, element isolation regions 12 (FIG. 1) filled with an insulating film comprising a silicon dioxide film are formed by means of known STI (shallow trench isolation) on a silicon substrate 1 constituting a semiconductor substrate. Active regions 13 (FIG. 1) comprising the silicon substrate 1 and enclosed by the element isolation regions 12 are formed as a result.

A pad oxide film 2 comprising a silicon dioxide film is then formed over the whole surface of the silicon substrate 1, and a P-well region is formed by a known method through this pad oxide film 2.

A first interlayer insulating film 7 comprising a silicon dioxide film or the like is then deposited (formed) on the silicon substrate 1, as shown in FIG. 4.

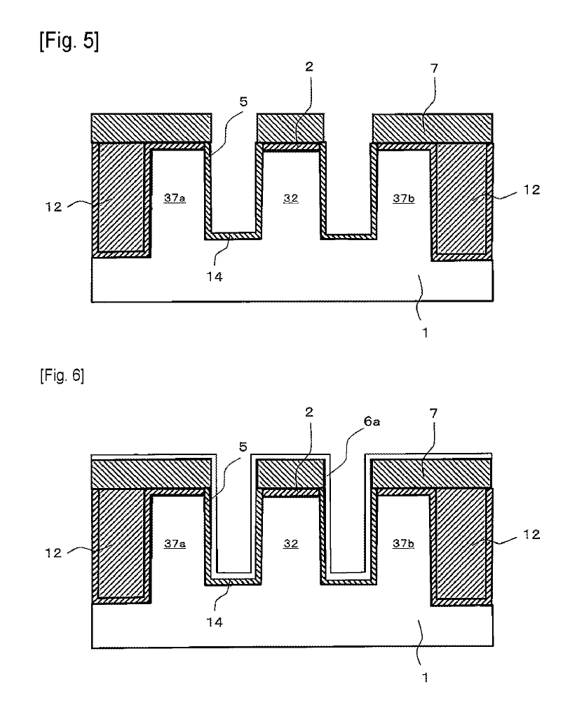

Next, as shown in FIG. 5, the first interlayer insulating film 7 is patterned using a resist (not depicted), the silicon substrate 1 is etched by means of dry etching, and gate trenches 14 are formed. After this, the surfaces (inner walls) of the gate trenches 14 are oxidized by means of thermal oxidation (ISSG: in-situ steam generation), whereby a gate insulating film 5 comprising a silicon dioxide film is formed.

Here, the gate trenches 14 extend continuously from the active regions 13 across the element isolation regions 12.

A barrier metal film comprising titanium nitride (TiN) constituting an electrode is formed next. The barrier metal film comprising titanium nitride (TiN) is formed under the same gas condition as in the related technology, but the film formation is divided into two stages and performed in situ in the first exemplary embodiment of the present invention, as will be described later.

First of all, as shown in FIG. 6, first titanium nitride 6a is formed to 1 nm by means of ALD (atomic layer deposition) employing titanium tetrachloride (TiCl₄) gas and ammonia (NH₃) gas, in such a way as to cover the gate insulating film 5. The film formation conditions in this case constitute a reaction rate-controlled condition in which the flow ratio of TiCl₄/NH₃ is substantially 1. The gas condition is optimized in such a way that coverage is 100%. In this example, when the trench width is 12 nm and the depth is 180 nm, the film formation conditions are such that the titanium tetrachloride (TiCl₄) gas and ammonia (NH₃) gas flow at a rate of 60 sccm respectively. However, the flow rate of titanium tetrachloride (TiCl₄) gas and the flow rate of ammonia (NH₃) gas may be adjusted in such a way that the coverage does not deteriorate.

It should be noted that the first titanium nitride 6a is referred to as the first barrier metal. The reaction rate-controlled condition is referred to as the first film formation condition.

Here, as mentioned above, titanium nitride (TiN) forms a discontinuous film when a film thereof is formed to 3 nm or less, so attention should be paid to a deterioration in adhesion with tungsten (W) which is formed subsequently.

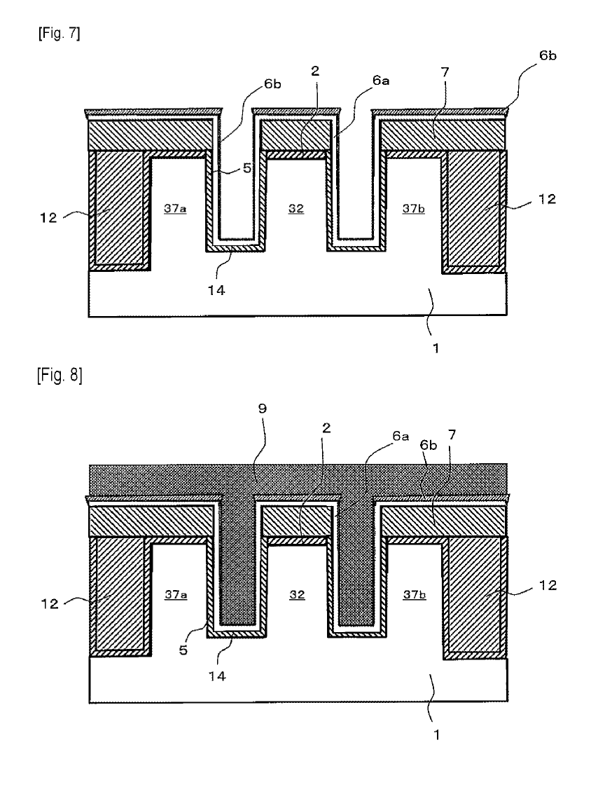

According to the first exemplary embodiment of the present invention, as shown in FIG. 7, second titanium nitride 6b is formed in such a way as to produce a film thickness of 3 nm together with the first titanium nitride 6a, by means of ALD (atomic layer deposition) employing titanium tetrachloride (TiCl₄) gas and ammonia (NH₃) gas, on the flat parts outside the gate trenches 14 on the upper part of the first titanium nitride 6a.

Here, a condition such that only a negligible amount of film formation takes place inside the gate trenches 14 (the coverage is 0%) is used as the supply rate-controlled condition, by narrowing the flow rate of titanium tetrachloride (TiCl₄) gas and increasing the flow rate of ammonia (NH₃) gas. In other words, the partial pressure of the titanium tetrachloride (TiCl₄) gas is reduced, whereby the flow rate of titanium tetrachloride (TiCl₄) gas is lowered, and the flow rate of ammonia (NH₃) gas is set to a high level.

It should be noted that the second titanium nitride 6b is referred to as the second barrier metal. The supply rate-controlled condition is referred to as the second film formation condition.

The thickness of the second barrier metal 6b film is therefore less than the thickness of the first barrier metal 6a film inside the gate trenches 14. In other words, the step coverage of the second barrier metal 6b formed under the second film formation condition is worse than the step coverage of the first barrier metal 6a formed under the first film formation condition.

The first titanium nitride 6a and the second titanium nitride 6b are continuously grown inside the same chamber, and as a result the films can be formed without any reduction in processing capacity. By additionally forming the second titanium nitride 6b, a continuous, thick film of titanium nitride (barrier metal) is produced on the flat parts outside the gate trenches 14, and it is possible to maintain adhesion with the metal electrodes comprising tungsten (W) which are subsequently formed. Furthermore, the inside of the gate trenches 14 has a far smaller surface area than a wafer surface area, and the film stress direction of the tungsten (W) is at right angles with respect to the flat part, so there is no reduction in adhesion with tungsten (W) even if the thickness of the titanium nitride film is reduced.

After this, as shown in FIG. 8, metal electrodes comprising tungsten (W) 9 are embedded by means of CVD. Here, the tungsten (W) 9 film is formed in two steps, namely a core-formation step and a main step.

That is to say, tungsten hexafluoride (WF₆) is reduced by diborane (B₂H₆) to form a core, and a tungsten wiring body is formed by WF₆/H₂ on the upper part of the first and second titanium nitride 6a, 6b, for example.

To describe this in greater detail, the titanium nitride (TiN) is first of all surface-treated with a stream of monosilane (SiH₄), and in the core-formation step, a film is formed by repeating alternate gas flows while purging with tungsten hexafluoride (WF₆) and monosilane (SiH₄) at a temperature of 350° C. and a pressure of 1000 Pa, for example. Instead of monosilane (SiH₄), it is equally possible to use diborane (B₂H₆) or hydrogen (H₂). When the trench width is 12 nm, diborane (B₂H₆) can reduce the specific resistance by the greatest amount. After this, in the main step for the tungsten (W), a film is formed by simultaneous streams of tungsten hexafluoride (WF₆) and hydrogen (H₂) under a temperature of 390° C. and a pressure of 10 666 Pa, for example.

Here, the thickness of the first titanium nitride 6a inside the gate trenches 14 is small, at 1 nm, so the cross-sectional area of the tungsten (W) 9 inside the gate trenches 14 is large and it is possible to reduce the resistance of the word lines 10.

In this process, the second titanium nitride 6b is additionally formed as a film on the flat parts outside the gate trenches 14, thereby increasing the thickness, so film peeling does not occur as a result of tensile stress in the metal electrodes comprising tungsten (W) 9.

At this stage, the gate trenches 14 are in a state in which they are completely filled by a laminated film comprising the first titanium nitride 6a, the second titanium nitride 6b and the tungsten (W) 9.

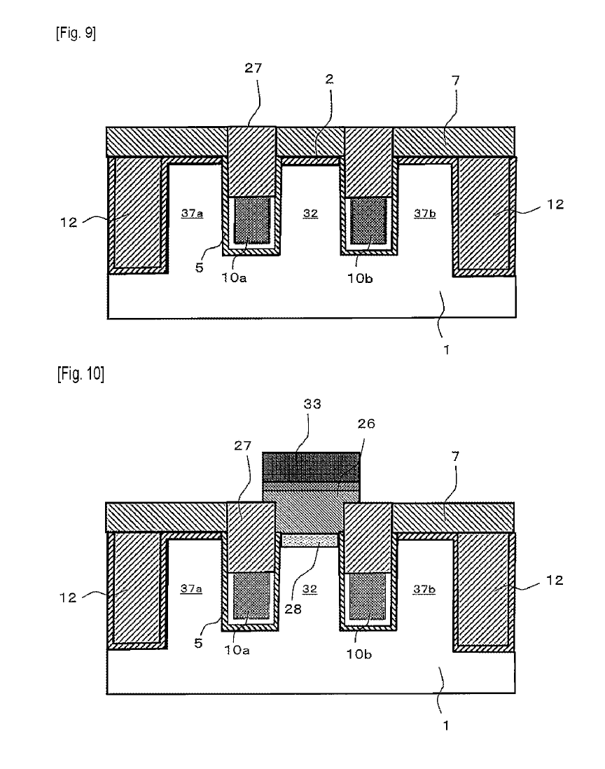

Next, as shown in FIG. 9, the laminated film comprising the first titanium nitride 6a, the second titanium nitride 6b and the tungsten (W) is etched back by means of dry etching, thereby forming embedded gate electrodes 10a, 10b comprising the first titanium nitride 6a, the second titanium nitride 6b and the tungsten (W), which are embedded inside the gate trenches 14. The embedded gate electrodes 10a, 10b constitute word lines. As a result of the embedded gate electrodes 10a, 10b being formed inside the gate trenches 14, a new trench is formed above the embedded gate electrodes 10a, 10b.

A cap insulating film 27 comprising silicon nitride (SiN) is then formed by means of CVD over the whole surface in such a way as to fill the new trench, and CMP (chemical mechanical polishing) is carried out in order to remove the surface silicon nitride (SiN) film.

The first barrier metal 6a, second barrier metal 6b, metal electrodes 9 and cap insulating film 27 therefore extend continuously inside the gate trenches 14 from the active regions 13 across the element isolation regions 12.

A bit line 26 is then formed, as shown in FIG. 10.

To describe this in detail, part of the first interlayer insulating film 7 is removed using a photolithography technique and a dry etching technique, and a bit contact connected to the upper surface of the bit line contact region 32 (FIG. 1) is formed. The bit contact is formed as a pattern with line-shaped openings extending in the same direction as the word lines 10 (the Y-direction in FIG. 1). The surface of the silicon substrate 1 is exposed at the region of intersection of the active regions with the pattern of the bit contact.

After the bit contact has been formed, N-type impurity (arsenic or the like) is ion-implanted and an N-type impurity diffusion layer 28 is formed in the vicinity of the silicon surface. The N-type impurity diffusion layer 28 which has been formed functions as a transistor source/drain region 28.

After this, a laminated film comprising a polysilicon film, a tungsten film and a silicon nitride film 33 etc. is formed by CVD, for example. A line-shaped pattern is then formed using a photolithography technique and a dry etching technique, and bit lines 26 are formed. The bit lines 26 are formed as a pattern extending in a direction intersecting the word lines 10 (the X-direction in FIG. 1). The polysilicon film and the source/drain region 28 under the bit lines 26 are connected at the region of the silicon surface exposed inside the bit contact.

Next, as shown in FIG. 2, a silicon nitride film covering the side surfaces of the bit lines 26 is formed, after which a liner film 34 covering the upper surface thereof is formed from a silicon nitride film or the like by means of CVD, for example.

A SOD film 35 which is a coating film is deposited in such a way as to fill the spaces between the bit lines, after which annealing is carried out in a high-temperature steam (H₂O) atmosphere in order to modify the film to a solid film. Planarization is carried out by means of CMP until the upper surface of the liner film 34 is exposed. After this, a capacitance contact is formed through the SOD film 35, liner film 34 and first interlayer insulating film 7 using a photolithography technique and a dry etching technique. In addition, polysilicon doped with N-type impurity (phosphorus or the like) is embedded inside the capacitance contact by means of CVD, for example. N-type impurity diffusion layers 29a, 29b are formed in the vicinity of the surface of capacitance contact regions 37a, 37b by the N-type impurity doped in the polysilicon. The N-type impurity diffusion layers 29a, 29b which have been formed function as transistor source/drain regions.

The polysilicon is then etched back and capacitance contact plugs 38a, 38b are completed. Capacitance contact pads 42a, 42b are formed using a photolithography technique and a dry etching technique.

A stopper nitride film 43 is formed using a silicon nitride film in such a way as to cover the capacitance contact pads 42a, 42b. A capacitor lower electrode 44 is formed by titanium nitride or the like over the capacitance contact pads 42a, 42b.

In addition, after a capacitance insulating film 45 has been formed in such a way as to cover the surface of the capacitor lower electrode 44, a capacitor of the polysilicon electrode 46 and a capacitor upper tungsten electrode 47 are formed.

After this, wiring 48 and a second interlayer insulating film 49 are formed over the capacitor upper tungsten electrode 47, thereby forming the semiconductor device 100.

The abovementioned semiconductor device 100 employs, as barrier metals, a combination of the first barrier metal 6a and the second barrier metal 6b which is a thinner film than the first barrier metal 6a, so a thin barrier metal film can be formed, adhesion with the metal electrodes can be maintained, and it is possible to control/manage the thickness of the thin film.

A preferred exemplary embodiment of the present invention was described above, but the present invention is not limited to the abovementioned exemplary embodiment and various modifications may be made within a scope that does not depart from the essentials of the present invention, and it goes without saying that any such modifications are also included within the scope of the present invention.

For example, in the first exemplary embodiment described above, a film in which the first titanium nitride 6a, second titanium nitride 6b and tungsten (W) 9 are stacked in succession is used as the embedded gate electrode (word line) 10, but the present invention is not limited to this and a number of variant examples may be adopted, as described below.

### Variant Examples

A nitrided first metal may be used as the first and second barrier metals instead of the first and second titanium nitride 6a, 6b. Furthermore, a second metal may be used as the metal electrode instead of the tungsten (W) 9.

In this case, the first metal and the second metal should be high-melting-point metals. The high-melting-point metals should be selected from the group consisting of tungsten, cobalt, titanium, nickel, molybdenum and tantalum.

The present invention was described above with reference to an exemplary embodiment, but the present invention is not limited to the abovementioned exemplary embodiment. Various modifications which will be understood by a person skilled in the art can be made to the constituent elements and details of the present invention, within the scope of the present invention.

### INDUSTRIAL APPLICABILITY

The present invention is not limited to embedded gate electrodes in a DRAM and is also applicable to embedded gate electrodes in general products including PRAMs (phase-change random access memories) and ReRAMs (resistive random access memories) etc.

This application claims priority on the basis of Japanese Patent Application 2013-021979 filed on Feb. 7, 2013, the disclosure of which is hereby incorporated in its entirety.

### KEY TO SYMBOLS

1 . . . Silicon substrate (semiconductor substrate)
2 . . . Pad oxide film
5 . . . Gate insulating film
6a . . . First titanium nitride (first barrier metal)
6b . . . Second titanium nitride (second barrier metal)
7 . . . First interlayer insulating film
9 . . . Tungsten (metal electrode)
10, 10a, 10b . . . Word line
12 . . . Element isolation region
13 . . . Active region
14 . . . Gate trench (trench)
26 . . . Bit line
27 . . . Cap insulating film
28 . . . Impurity diffusion layer (source/drain region)
29a, 29b . . . Impurity diffusion layer
32 . . . Bit line contact region
34 . . . Liner insulating film
35 . . . SOD film
37a . . . First capacitance contact region
37b . . . Second capacitance contact region
38a . . . First capacitance contact plug
38b . . . Second capacitance contact plug
42a . . . First capacitance contact pad
42b . . . Second capacitance contact pad
43 . . . Stopper nitride film
44 . . . Capacitor lower electrode
45 . . . Capacitance insulating film
46 . . . Capacitor upper polysilicon electrode
47 . . . Capacitor upper tungsten electrode
48 . . . Wiring
49 . . . Second interlayer insulating film
100 . . . Semiconductor device
Tr1 . . . First cell transistor
Tr2 . . . Second cell transistor

1. A semiconductor device comprising:
an active region on a semiconductor substrate;
a trench inside the active region having a lower part and an upper part;
a gate insulating film covering the inner wall surface of the trench;
a first barrier metal covering the trench lower part with the gate insulating film interposed;
a second barrier metal covering the first barrier metal;
a metal electrode which covers the second barrier metal and fills the trench lower part; and
a cap insulating film filling the trench upper part, wherein the film thickness of the second barrier metal is less than the film thickness of the first barrier metal.

2. The semiconductor device as claimed in claim 1, wherein the semiconductor substrate further comprises an element isolation region surrounding the active region, the trench extends continuously from the active region across the element isolation region, and the first barrier metal, second barrier metal, metal electrode and cap insulating film extend continuously inside the trench from the active region across the element isolation region.

3. The semiconductor device as claimed in claim 1, wherein the first and second barrier metals each comprise a nitrided first metal, and the metal electrode comprises a second metal.

4. The semiconductor device as claimed in claim 3, wherein the first metal comprises a high-melting-point metal.

5. The semiconductor device as claimed in claim 3, wherein the second metal comprises a high-melting-point metal.

6. The semiconductor device as claimed in claim 4, wherein the high-melting-point metal is selected from the group consisting of tungsten, cobalt, titanium, nickel, molybdenum and tantalum.

7. The semiconductor device as claimed in claim 1, wherein the film thickness of the first barrier metal is 1 nm.

8. The semiconductor device as claimed in claim 7, wherein the total film thickness of the first and second barrier metals on a flat part outside the trench is 3 nm.

9. A method for manufacturing a semiconductor device, comprising:
forming a trench in a semiconductor substrate;
forming a gate insulating film inside the trench;
forming a first barrier metal on the gate insulating film under a first film formation condition;
forming a second barrier metal on the first barrier metal under a second film formation condition different than the first film formation condition;
forming a metallic material on the second barrier metal in such a way as to fill the trench;
removing the first barrier metal, second barrier metal and metal at the upper part of the trench; and
filling the trench upper part with a cap insulating film.

10. The method for manufacturing a semiconductor device as claimed in claim 9, wherein the coverage of forming the second barrier metal under the second film formation condition is worse than the coverage of forming the first barrier metal under the first film formation condition.

11. The method for manufacturing a semiconductor device as claimed in claim 10, wherein the first film formation condition is a reaction rate-controlled condition, and the second film formation condition is a supply rate-controlled condition.

12. The method for manufacturing a semiconductor device as claimed in claim 10, wherein the first and second barrier metals each comprise a nitrided first metal, and the metal electrode comprises a second metal.

13. The method for manufacturing a semiconductor device as claimed in claim 12, wherein the first metal comprises a high-melting-point metal.

14. The method for manufacturing a semiconductor device as claimed in claim 12, wherein the second metal comprises a high-melting-point metal.

15. The method for manufacturing a semiconductor device as claimed in claim 13, wherein the high-melting-point metal is selected from the group consisting of tungsten, cobalt, titanium, nickel, molybdenum and tantalum.

16. The method for manufacturing a semiconductor device as claimed in claim 10, wherein the film thickness of the first barrier metal is 1 nm.

17. The method for manufacturing a semiconductor device as claimed in claim 16, wherein the total film thickness of the first and second barrier metals on a flat part outside the trench is 3 nm.
